(19) United States
(12) Patent Application Publication
(10) Pub. No.: US 2026/0033369 A1
(43) Pub. Date: Jan. 29, 2026

(54) SEMICONDUCTOR PACKAGE

(71) Applicant: Samsung Electronics Co., Ltd., Suwon-si (KR)

(72) Inventors: Daeyoung JUNG, Suwon-si (KR); Jongbo SHIM, Suwon-si (KR); Jangwoo LEE, Suwon-si (KR)

(73) Assignee: Samsung Electronics Co., Ltd., Suwon-si (KR)

(21) Appl. No.: 19/020,281

(22) Filed: Jan. 14, 2025

(30) Foreign Application Priority Data
Jul. 24, 2024 (KR) 10-2024-0098031

(51) Int. Cl. H01L 23/00; H01L 23/13; H01L 23/538; H01L 25/07

(52) U.S. Cl. CPC H01L 24/32; H01L 23/13; H01L 24/16; H01L 24/48; H01L 24/73; H01L 25/071; H01L 23/5385; H01L 2224/16227; H01L 2224/26145; H01L 2224/26175; H01L 2224/32137; H01L 2224/32225; H01L 2224/48227; H01L 2224/73204; H01L 2224/73215; H01L 2225/06541

(57) ABSTRACT

A semiconductor package including a package substrate defining a cavity therein; a first semiconductor chip on the package substrate; a first bump between the package substrate and the first semiconductor chip, the first bump electrically connecting the package substrate and the first semiconductor chip; a second semiconductor chip on the package substrate, the second semiconductor chip being at least partially in the cavity; a first bonding wire electrically connecting the package substrate and the second semiconductor chip; and an underfill layer covering the first bump and at least a portion of the first bonding wire.

### CROSS-REFERENCE TO RELATED APPLICATION

This application claims priority to Korean Patent Application No. 10-2024-0098031, filed in the Korean Intellectual Property Office on Jul. 24, 2024, the entire contents of which are hereby incorporated by reference.

### BACKGROUND

The present disclosure relates to semiconductor packages.

As electronic devices become smaller with increased high performance, a greater number of functions are being implemented in smaller space. According to package-on-package (POP) techniques, two or more independent packages are stacked vertically such that each package functions individually while acting as a single package as a whole. According to this, there is an advantage in that higher performance can be achieved while space is saved.

The package-on-package may be manufactured through various kinds of manufacturing processes. In manufacturing processes, defects may occur in the package or manufacturing equipment as other components already manufactured by a specific manufacturing process are physically deformed. It may thus be advantageous to reduce (and/or minimize) unnecessary mutual interference between components in the manufacturing process.

The information described above is intended to improve understanding of the background of the present disclosure, and may include information that does not constitute the related art.

### SUMMARY

Some example embodiments of the inventive concepts provide a semiconductor package that includes a package substrate defining a cavity therein; a first semiconductor chip on the package substrate; a first bump between the package substrate and the first semiconductor chip, the first bump electrically connecting the package substrate and the first semiconductor chip; a second semiconductor chip on the package substrate, the second semiconductor chip being at least partially in the cavity; a first bonding wire electrically connecting the package substrate and the second semiconductor chip; and an underfill layer covering the first bump and at least a portion of the first bonding wire.

Some example embodiments of the inventive concepts further provide a semiconductor package that includes a first package; and a second package on the first package, the second package including one or more semiconductor chips. The first package includes a first package substrate defining a cavity therein; an interposer spaced apart from the first package substrate, the interposer electrically connecting the first package and the second package; a vertical connecting member between the first package substrate and the interposer, the vertical connecting member electrically connecting the first package substrate and the interposer; a first semiconductor chip on the first package substrate; a first bump between the first package substrate and the first semiconductor chip, the first bump electrically connecting the first package substrate and the first semiconductor chip; a second semiconductor chip on the first package substrate, the second semiconductor chip at least partially in the cavity; a first bonding wire electrically connecting the first package substrate and the second semiconductor chip; and an underfill layer covering the first bump and at least a portion of the first bonding wire.

Some example embodiments of the inventive concepts still further provide a semiconductor package that includes a first package substrate defining a cavity therein; a second package substrate spaced apart from the first package substrate; a vertical connecting member between the first package substrate and the second package substrate, the vertical connecting member connecting the first package substrate and the second package substrate; a first semiconductor chip on the first package substrate; a first bump between the first package substrate and the first semiconductor chip, the first bump electrically connecting the first package substrate and the first semiconductor chip; a second semiconductor chip on the first package substrate, the second semiconductor chip at least partially in the cavity; a first bonding wire electrically connecting the first package substrate and the second semiconductor chip; and an underfill layer covering the first bump and at least a portion of the first bonding wire.

According to some example embodiments of the present disclosure, since the underfill layer covers the bump and the bonding wire together, connection failure and/or short circuit due to physical deformation (e.g., sweeping or breaking) of the bonding wire can be limited and/or prevented.

According to some example embodiments of the present disclosure, since at least a portion of the semiconductor chip is accommodated in the cavity, the length and height of the bonding wire can be reduced. As a result, the bonding wire can be covered by the underfill layer more effectively, and the effects of limiting and/or preventing physical deformation of the bonding wire can be increased (and/or maximized). Further, as length of the bonding wire decreases, cost can be reduced. It is thus possible to limit and/or prevent the electrical performance from deteriorating due to the inductance component of the bonding wire. As a result, signal integrity and/or power integrity of the semiconductor package can be improved.

According to some example embodiments of the present disclosure, by impregnating a metal core ball in the outer vertical connecting member, the mechanical strength of the package can be reinforced. As a result, warpage, which is a phenomenon in which the package is bent or distorted due to environmental changes such as heat or pressure, can be limit and/or prevented. As the mechanical strength is reinforced, the package may maintain a uniform structure, and the bonding line thickness (BLT) may be kept uniform.

The effects that can be obtained through the present disclosure are not limited to those described above. Technical effects not mentioned herein will be clearly understood by those skilled in the art from the description of the present disclosure described below.

### BRIEF DESCRIPTION OF THE DRAWINGS

The above and other objects, features and advantages of the present disclosure will become more apparent to those of ordinary skill in the art in view of the following description of some example embodiments thereof with reference to the accompanying drawings, in which:

FIG. 1 is a cross-sectional view illustrating an example of a first package;

FIG. 2 is a plan view illustrating an example of the first package;

FIG. 3 is a cross-sectional view illustrating an example of a semiconductor package;

FIG. 4 is a plan view illustrating an example of the first package included in the semiconductor package;

FIG. 5 is a cross-sectional view illustrating an example of a semiconductor package;

FIGS. 6 and 7 are cross-sectional views illustrating examples of the semiconductor package according to some example embodiments;

FIG. 8 is a cross-sectional view illustrating an example of the semiconductor package;

FIG. 9 is a cross-sectional view illustrating an example of the semiconductor package;

FIGS. 10 and 11A are cross-sectional views illustrating examples of the semiconductor package according to some example embodiments;

FIGS. 11B and 11C are plan views illustrating examples of the first package according to some example embodiments;

FIG. 12 is a cross-sectional view illustrating an example of the semiconductor package according to some example embodiments; and

FIGS. 13, 14, 15, 16, 17, 18, 19, 20 and 21 are cross-sectional views illustrating a process of manufacturing the semiconductor package according to some example embodiments.

### DETAILED DESCRIPTION

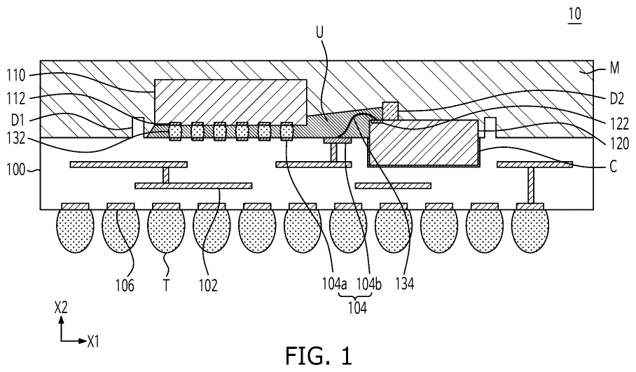

Hereinafter, various example embodiments of the present disclosure will be described with reference to FIGS. 1 to 21. Throughout the description, the same reference numerals may refer to the same components.

Hereinafter, the terminology, for example, “at least one of A, B, and C” and similar language (e.g., “at least one selected from the group consisting of A, B, and C”) may be construed as A only, B only, C only, or any combination of two or more of A, B, and C, such as, for instance, ABC, AB, BC, and AC.

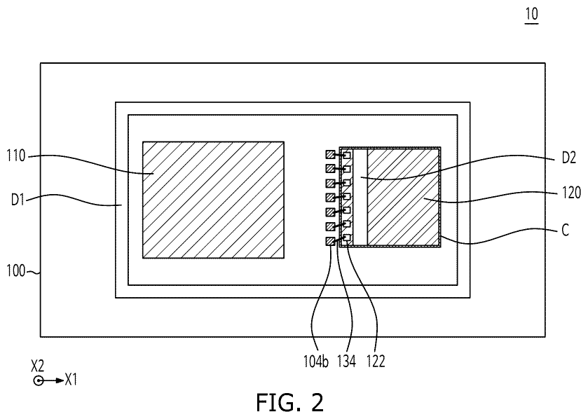

FIG. 1 is a cross-sectional view illustrating an example of a first package 10, and FIG. 2 is a plan view illustrating an example of the first package 10. For convenience of explanation, the illustrations of an underfill layer U and a molding layer M are omitted from the plan view of FIG. 2.

Referring to FIGS. 1 and 2, a semiconductor package may include the first package 10. The first package 10 may include a first package substrate 100, and a first semiconductor chip 110 and a second semiconductor chip 120 disposed on the first package substrate 100. Hereinbelow, a left-right direction or horizontal direction may be a first direction X1 parallel to an upper surface of the first package substrate 100. Further, an up-down direction or vertical direction may be a second direction X2 perpendicular to the upper surface of the first package substrate 100.

The first package substrate 100 may be a printed circuit board (PCB) or a redistributed layer (RDL). In some example embodiments, the PCB may be a multilayer PCB having a substrate base formed by stacking a plurality of base layers. In some example embodiments, each of a plurality of base layers forming the substrate base may include at least one material selected from phenol resin, epoxy resin, and polyimide. For example, each of the plurality of base layers of the substrate base may include at least one material selected from among Flame Retardant 4 (FR4), tetrafunctional epoxy, polyphenylene ether, epoxy/polyphenylene oxide, bismaleimidetriazine (BT), thermount, cyanate ester, polyimide, and liquid crystal polymer.

The first package substrate 100 may include a first wiring layer 102. The first wiring layer 102 may include a wiring pattern and a wiring via. The wiring pattern may be disposed on an upper surface and/or a lower surface of each of a plurality of base layers. For example, the wiring pattern may include an electrolytically deposited (ED) copper foil, a rolled-annealed (RA) copper foil, a stainless steel foil, an aluminum foil, ultra-thin copper foils, sputtered copper, copper alloys, etc. The wiring via may electrically connect between the wiring patterns. The wiring via may be formed to extend through at least one of the plurality of base layers. In some example embodiments, the wiring via may include copper, nickel, stainless steel, or beryllium copper.

The first package substrate 100 may include one or more upper pads 104 and one or more lower pads 106. For example, the one or more upper pads 104 may be formed on the upper surface of the first package substrate 100. The one or more upper pads 104 may be electrically connected to the first wiring layer 102 included in the first package substrate 100. One or more lower pads 106 may be formed on a lower surface of the first package substrate 100. The one or more lower pads 106 may be electrically connected to the first wiring layer 102 included in the first package substrate 100. For example, the first wiring layer 102 may electrically connect the upper pads 104 to the lower pads 106.

A cavity C may be formed in the first package substrate 100. For example, the cavity C may be formed in the first package substrate 100 as a portion of the upper surface of the first package substrate 100 and may be recessed toward the lower surface side. For example, the first package substrate 100 may define the cavity C at an upper surface of the first package substrate 100 and the cavity C may be recessed toward the lower surface side of the first package substrate 100. Hereinbelow, the upper surface of the first package substrate 100 may include a bottom surface of the cavity C.

The second semiconductor chip 120 may be disposed on the first package substrate 100 with at least a portion thereof being accommodated in the cavity C. For example, the second semiconductor chip 120 may be on the first package substrate 100 at least partially in the cavity C, so that for example, an upper portion of the second semiconductor chip 120 may extend out of (e.g., from) the cavity C. For example, the second semiconductor chip 120 may be disposed on the bottom surface of the cavity C. An adhesive member (e.g., die attach film (DAF), etc.) may be interposed between the bottom surface of the cavity C and the second semiconductor chip 120.

A first dam D1 may be formed on the first package substrate 100. For example, the first dam D1 may be formed as the substrate base protrudes from the upper surface of the first package substrate 100 in a vertical direction (in the second direction X2). The first dam D1 may be formed to surround a partial region of the first package substrate 100. For example, the first dam D1 may be formed to surround a region on the first package substrate 100 where the first semiconductor chip 110 and the second semiconductor chip 120 are disposed. The first dam D1 may be a solder resist dam (SR Dam), but is not limited thereto. The first dam D1 may have a rectangular shape in cross-section, but is not limited thereto.

The upper pads 104 may include a first upper pad 104a electrically connected to the first semiconductor chip 110. A first chip pad 112 electrically connected to the first upper pad 104a may be formed on one surface of the first semiconductor chip 110. For example, the first upper pad 104a may be electrically connected to the first chip pad 112 of the first semiconductor chip 110. The surface of the first semiconductor chip 110 where the first chip pad 112 is formed may be an active surface side of the first semiconductor chip 110, but some example embodiments are not limited thereto.

The first package 10 may include a first bump 132 interposed between the first package substrate 100 and the first semiconductor chip 110 to electrically connect the first package substrate 100 and the first semiconductor chip 110. For example, the first semiconductor chip 110 may be disposed such that the surface where the first chip pad 112 is formed faces the first package substrate 100. The first bump 132 may be connected to the first chip pad 112 and the first upper pad 104a. For example, the first semiconductor chip 110 and the first package substrate 100 may be electrically connected to each other through the first bump 132, and signals and/or power may be transferred between the first semiconductor chip 110 and the first package substrate 100 through the first bump 132.

The upper pads 104 may include a second upper pad 104b electrically connected to the second semiconductor chip 120. Further, a second chip pad 122 electrically connected to the second upper pad 104b may be formed on the second semiconductor chip 120. For example, the second upper pad 104b may be electrically connected to the second chip pad 122 of the second semiconductor chip 120. A surface of the second semiconductor chip 120 where the second chip pad 122 is formed may be an active surface side of the second semiconductor chip 120, but some example embodiments are not limited thereto.

The first package 10 may include a first bonding wire 134 electrically connecting the first package substrate 100 and the second semiconductor chip 120. For example, the second upper pad 104b may be formed on a periphery of the cavity C of the upper surface of the first package substrate 100. Further, the second semiconductor chip 120 may be disposed on the bottom surface of the cavity C such that the surface where the second chip pad 122 is formed faces upward and at least a portion of the second semiconductor chip 120 is accommodated in the cavity C. The first bonding wire 134 may be connected to the second chip pad 122 and the second upper pad 104b. For example, the second semiconductor chip 120 and the first package substrate 100 may be electrically connected to each other through the first bonding wire 134, and signals and/or power may be transferred between the second semiconductor chip 120 and the first package substrate 100 through the first bonding wire 134.

The first bonding wire 134 may be formed by a wire bonding process. The first bonding wire 134 may include nickel (Ni), antimony (Sb), bismuth (Bi), zinc (Zn), indium (In), palladium (Pd), platinum (Pt), aluminum (Al), copper (Cu), molybdenum (Mo), titanium (Ti), gold (Au), silver (Ag), chromium (Cr), tin (Sn), etc., but is not limited thereto. The first bonding wire 134 may include any conductive material.

The first package 10 may include a second dam D2. For example, the second dam D2 may be disposed on the second semiconductor chip 120. The second dam D2 may have a width in a direction (e.g., in the first direction X1) parallel to an upper surface of the second semiconductor chip 120, and may have a height in a direction (e.g., in the second direction X2) perpendicular to the upper surface of the second semiconductor chip 120. The second dam D2 may be positioned in a direction opposite to a direction of the first semiconductor chip 110 side with respect to the second chip pad 122. Further, the first bonding wire 134 may be positioned between the first bump 132 and the second dam D2.

The second dam D2 may include an epoxy resin, but is not limited thereto. For example, the second dam D2 may be formed of any material such as silicon, polyimide, polyurethane, etc. The second dam D2 may have a rectangular or triangular shape in cross-section, but is not limited thereto.

The first package 10 may include an underfill layer U on the first package substrate 100. The underfill layer U may be positioned in the region surrounded by the first dam D1. The underfill layer U may include an underfill resin such as an epoxy resin, a silica filler, or flux, but is not limited thereto. The underfill layer U may be formed by a capillary underfill (CUF) process or a molded underfill (MUF) process. In some example embodiments in which it is formed by the molded underfill (MUF) process, the underfill layer U may be integrated with the molding layer M which will be described below.

The underfill layer U may cover the first bump 132 and at least a portion of the first bonding wire 134. For example, the underfill layer U may cover the first bump 132 and at least a portion of the first bonding wire 134 together. The underfill layer U may also cover a space between the first semiconductor chip 110 and the first package substrate 100 and a space between the first semiconductor chip 110 and the second dam D2. The underfill layer U may be in contact with at least a portion of the second dam D2 (e.g., at least a portion of a side surface of the second dam D2) and/or at least a portion of the second semiconductor chip 120 (e.g., at least a portion of a side surface of the second semiconductor chip 120).

The underfill layer U may limit and/or prevent deformation of components such as the first bump 132, the first bonding wire 134, etc. For example, by covering not only the first bump 132 but also the first bonding wire 134, the underfill layer U may limit and/or prevent connection failure and/or short circuits, etc. due to physical deformation (e.g., sweeping or breaking) of the first bonding wire 134. Further, the underfill layer U may eliminate a space where foreign substances or humidity may penetrate, and may limit and/or prevent electrical migration. The first dam D1 and/or the second dam D2 may limit and/or prevent the underfill layer U from overflowing.

According to some example embodiments in which at least a portion of the second semiconductor chip 120 is accommodated in the cavity C formed in the first package substrate 100, length and height of the first bonding wire 134 may be reduced compared to comparative examples. As a result, the first bonding wire 134 can be more effectively covered by the underfill layer U, which may increase (and/or maximize) the effect of limiting and/or preventing physical deformation of the first bonding wire 134. Further, as the length of the first bonding wire 134 decreases compared to the comparative examples, cost may be reduced, and the degradation of electrical performance due to the inductance component of the first bonding wire 134 may be limited and/or prevented. As a result, signal integrity (SI) and/or power integrity (PI), etc. of the semiconductor package may be improved.

The side surface of the second semiconductor chip 120 may be slightly spaced apart from a wall surface of the cavity C. In some example embodiments, a region between the second semiconductor chip 120 and the cavity C may serve as a trench. An underfill solution may permeate into a space between the second semiconductor chip 120 and the wall surface of the cavity C, forming the underfill layer U also in the space between the second semiconductor chip 120 and the wall surface of the cavity C. Additionally or alternatively, a molding solution may permeate into the space between the second semiconductor chip 120 and the wall surface of the cavity C, forming the molding layer M in the space between the second semiconductor chip 120 and the wall surface of the cavity C, which will be described below.

The first package 10 may include the molding layer M covering the first package substrate 100, the first semiconductor chip 110, the second semiconductor chip 120, the second dam D2, and the underfill layer U. For example, the molding layer M may cover the excess spaces of the spaces on the first package substrate 100 in the first package 10 excluding the spaces occupied by the other components (the first semiconductor chip 110, the second semiconductor chip 120, the underfill layer U, the second dam D2, etc.).

The molding layer M may include an epoxy molding compound (EMC). However, some example embodiments are not limited to the above, and the molding layer M may include various materials such as epoxy-based materials, thermosetting materials, thermoplastic materials, UV-treated materials, etc.

One or more external terminals T may be attached onto the one or more lower pads 106. The first package substrate 100 may be connected to an external device through the external terminal T. For example, the first package substrate 100 may be mounted on a system board. In some example embodiments, the external terminal T of the first package substrate 100 may be electrically connected to a pad of the system board. For example, the first package substrate 100 may be electrically connected to the system board through the external terminal T.

The first semiconductor chip 110 may be a modem chip including a communication processor (CP), and the second semiconductor chip 120 may be a memory chip (e.g., a DRAM chip) or a memory controller chip. For example, the first semiconductor chip 110 may include the communication processor (CP), and the second semiconductor chip 120 may include a volatile memory device (e.g., random access memory (RAM), dynamic RAM (DRAM), static RAM (SRAM)), and/or a controller that controls the volatile memory device. However, some example embodiments are not limited to the above, and each of the first semiconductor chip 110 and the second semiconductor chip 120 may be any semiconductor chip.

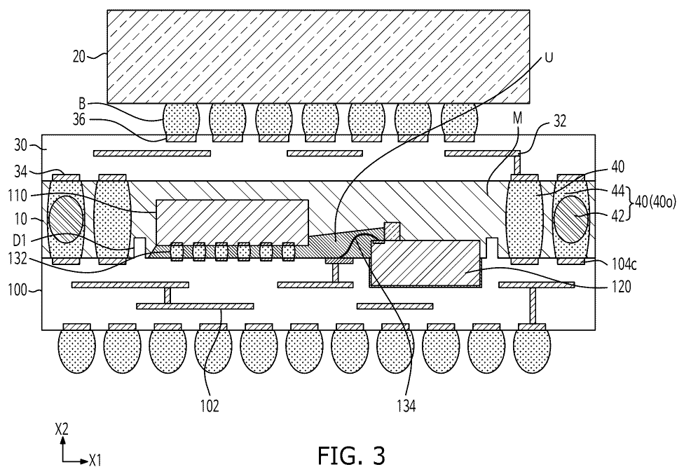

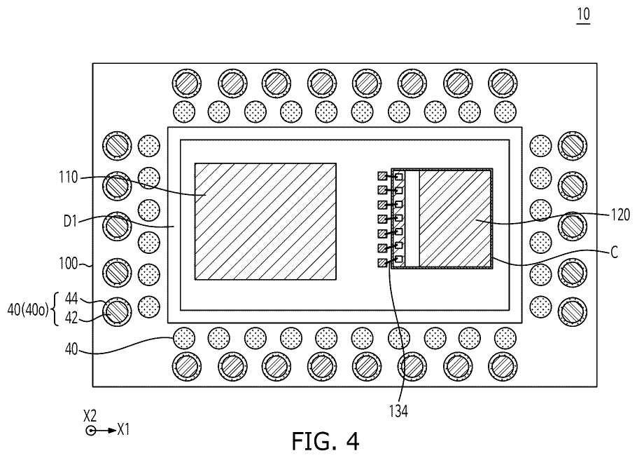

FIG. 3 is a cross-sectional view illustrating an example of a semiconductor package, and FIG. 4 is a plan view illustrating an example of the first package 10 included in the semiconductor package. For convenience of explanation, the illustrations of the underfill layer U, the molding layer M, and a second package substrate are omitted from the plan view of FIG. 4. Most of the description provided above with reference to FIGS. 1 and 2 may be equally/similarly applicable to the first package 10 of FIGS. 3 and 4. Hereinbelow, the elements or operations already described above with reference to FIGS. 1 and 2 will not be described or may be briefly described below, and the description will focus on additions/changes.

Referring to FIGS. 3 and 4, the semiconductor package may include the first package 10. The first package 10 may include the first package substrate 100, the first semiconductor chip 110 and the second semiconductor chip 120 disposed on the first package substrate 100, the first bump 132 electrically connecting the first package substrate 100 and the first semiconductor chip 110, the first bonding wire 134 electrically connecting the first package substrate 100 and the second semiconductor chip 120, the underfill layer U covering the first bump 132 and at least a portion of the first bonding wire 134, the second package substrate 30, a vertical connecting member 40, and the molding layer M.

The second package substrate 30 may be disposed to be spaced apart from the first package substrate 100. The second package substrate 30 may be a printed circuit board (PCB) or a redistributed layer (RDL). The second package substrate 30 may include a second wiring layer 32, and the second wiring layer 32 may include a wiring pattern and a wiring via.

The second package substrate 30 may include one or more lower pads 34 and/or one or more upper pads 36. For example, the one or more lower pads 34 may be formed on a lower surface of the second package substrate 30. Additionally or alternatively, the one or more upper pads 36 may be formed on an upper surface of the second package substrate 30. The second wiring layer 32 may be electrically connected to the upper pads 36 and/or the lower pads 34 of the second package substrate 30. For example, the second wiring layer 32 may electrically connect the upper pads 36 and the lower pads 34 to each other.

The vertical connecting member 40 may be interposed between the first package substrate 100 and the second package substrate 30 to connect the first package substrate 100 and the second package substrate 30. The vertical connecting member 40 may be positioned outside the region surrounded by the first dam D1 of the first package substrate 100. The vertical connecting member 40 may extend between the first package substrate 100 and the second package substrate 30 in the second direction X2 perpendicular to the upper surface of the first package substrate 100.

The vertical connecting member 40 may electrically connect the first package substrate 100 and the second package substrate 30. For example, the first package substrate 100 may include a third upper pad 104c electrically connected to the first wiring layer 102 of the first package substrate 100. For example, the third upper pad 104c may be formed on the upper surface of the first package substrate 100. The vertical connecting member 40 may be connected to the third upper pad 104c of the first package substrate 100 and the lower pad 34 of the second package substrate 30. The semiconductor chip included in the first package 10 and the semiconductor chip included in a second package 20 may be electrically connected to each other through the vertical connecting member 40.

The vertical connecting member 40 may be a conductive post, a conductive pillar, a conductive bump, a solder ball, a through mold via (TMV), a vertical bonding wire, etc. For example, the vertical connecting member 40 may be a conductive post including Sn—Ag—Cu (SAC) or Sn—Ag (SA), but is not limited thereto.

An outer vertical connecting member 400 disposed at an edge of the vertical connecting member 40 may include a metal core ball 42 therein. For example, the outer vertical connecting member 400 may be a vertical connecting member with the metal core ball 42 impregnated in the conductive member 44. For example, the conductive member 44 may include Sn—Ag—Cu (SAC), Sn—Ag (SA), etc., and the metal core ball 42 may include copper (Cu), etc., but is not limited thereto. As described above, impregnating the metal core ball 42 in the outer vertical connecting member 400 may reinforce the mechanical strength of the package. As a result, warpage, which is a phenomenon in which the package is bent or distorted due to environmental changes such as heat or pressure, may be limited and/or prevented. As the mechanical strength is reinforced, the package may maintain a uniform structure, and the bonding line thickness (BLT) may be kept uniform.

The molding layer M may cover the spaces between the first package substrate 100 and the second package substrate 30 excluding the spaces occupied by the other components (the first semiconductor chip 110, the second semiconductor chip 120, the underfill layer U, the second dam D2, the vertical connecting member 40, etc.).

The semiconductor package may further include the second package 20 disposed on the first package 10 and including one or more semiconductor chips. The second package substrate 30 may serve as an interposer electrically connecting the first package 10 and the second package 20.

The semiconductor package may include a connecting terminal B electrically connecting the second package substrate 30 and the second package 20. The connecting terminal B may be electrically connected to the upper pads 36 of the second package substrate 30 and the second package 20. Signals and/or power may be transferred between the first package 10 and the second package 20 through the connecting terminal B. Additionally or alternatively, signals and/or power may be transferred between the external device and the second package 20 through the connecting terminal B, the second package substrate 30, the vertical connecting member 40, the first package substrate 100, and the external terminal T.

The second package 20 may include a non-volatile memory device (e.g., one or more non-volatile memory chips). For example, the non-volatile memory device may be at least one of an electrically erasable programmable read-only memory (EEPROM), a flash memory, a magnetic random access memory (MRAM), a spin-transfer torque MRAM (STT-MRAM), a ferroelectric RAM (FeRAM), a phase change memory (PRAM), a resistive RAM (RRAM), a nanotube RRAM, a polymer RAM (PoRAM), a nano floating gate memory (NFGM), a holographic memory, a molecular electronics memory device, or an insulator resistance change memory. However, some example embodiments are not limited to the above, and the semiconductor chip included in the second package 20 may be any semiconductor chip.

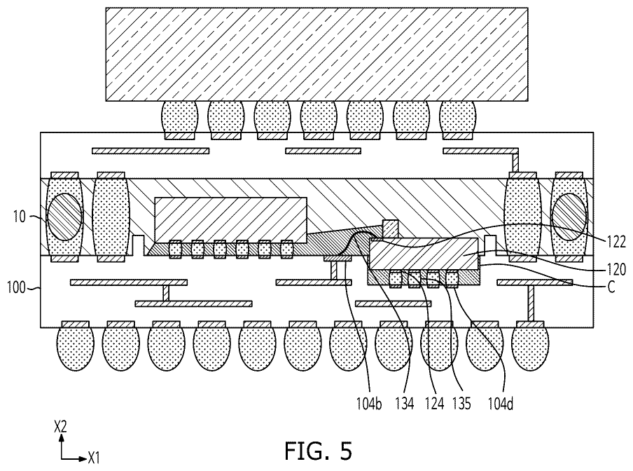

In FIG. 3 and the subsequent drawings (e.g., FIGS. 5 to 21), the semiconductor package is illustrated as a package-on-package (POP) structure in which the first package 10 and the second package 20 are stacked, but some example embodiments are not limited thereto. The technical idea of the present disclosure may also be applicable to a semiconductor package in which the second package 20 is not included. For example, the semiconductor package may be a semiconductor package including the first package 10 only, and in some example embodiments, the second package substrate 30 (interposer) may be omitted or replaced with a metal layer and/or an insulating layer. Further, in some example embodiments, the vertical connecting member 40 may be omitted or replaced with a support member.

FIG. 5 is a cross-sectional view illustrating an example of the semiconductor package. Most of the description provided above with reference to FIGS. 1 to 4 may be equally/similarly applicable to the description below. Hereinbelow, the elements or operations already described above with reference to FIGS. 1 to 4 will not be described or will be briefly described below, and the description will focus on additions/changes.

Referring to FIG. 5, the first package 10 may include a second bump 135 interposed between the first package substrate 100 and the second semiconductor chip 120 to electrically connect the first package substrate 100 and the second semiconductor chip 120.

For example, the second chip pad 122 may be formed on the upper surface of the second semiconductor chip 120, and a third chip pad 124 may be formed on a lower surface of the second semiconductor chip 120. The upper surface of the second semiconductor chip 120 where the second chip pad 122 is formed may be the active surface side of the second semiconductor chip 120, and the lower surface of the second semiconductor chip 120 where the third chip pad 124 is formed may be an inactive surface side of the second semiconductor chip 120. For example, the second semiconductor chip 120 may be a semiconductor chip in which a signal wiring layer is formed on the active surface side and a power wiring layer is formed on the inactive surface side. For example, the second semiconductor chip 120 may be a semiconductor chip to which a back side power delivery network (BSPDN) is applied. In some example embodiments, the second chip pad 122 may be electrically connected to the signal wiring layer of the second semiconductor chip 120, and the third chip pad 124 may be electrically connected to the power wiring layer of the second semiconductor chip 120. The second upper pad 104b may be formed on the periphery of the cavity C of the upper surface of the first package substrate 100, and a fourth upper pad 104d may be formed on the bottom surface of the cavity C.

The second semiconductor chip 120 may be disposed on the first package substrate 100 with at least a portion thereof being accommodated in the cavity C. In some example embodiments, the second semiconductor chip 120 may be disposed such that the surface where the second chip pad 122 is formed faces upward and the surface where the third chip pad 124 is formed faces the bottom surface of the cavity C (e.g., faces the fourth upper pad 104d).

The first bonding wire 134 may connect the second chip pad 122 and the second upper pad 104b. Further, the second bump 135 may connect the third chip pad 124 and the fourth upper pad 104d. For example, the second semiconductor chip 120 and the first package substrate 100 may be electrically connected to each other through the first bonding wire 134 and the second bump 135. Signals may be transferred between the first package substrate 100 and the second semiconductor chip 120 through the first bonding wire 134, and power may be transferred between the first package substrate 100 and the second semiconductor chip 120 through the second bump 135, although some example embodiments are not limited thereto.

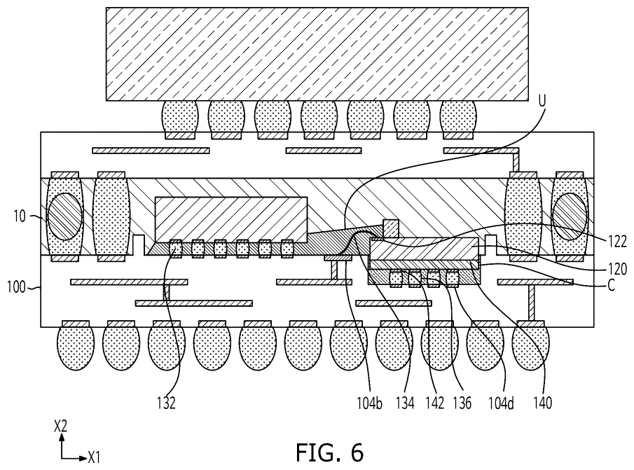

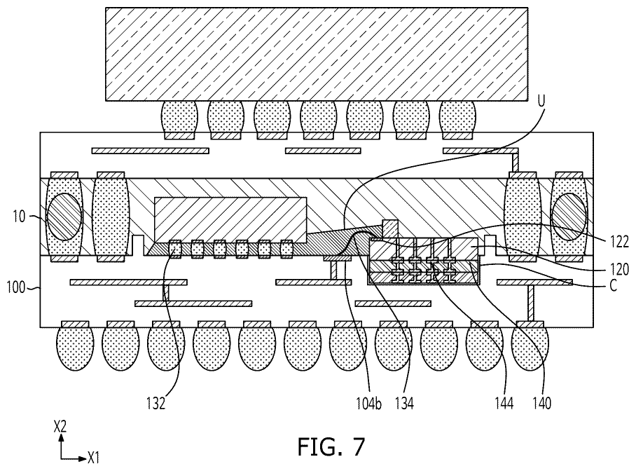

FIGS. 6 and 7 are cross-sectional views illustrating some examples of the semiconductor package. Referring to FIGS. 6 and 7, the first package 10 may include a third semiconductor chip 140 accommodated in the cavity C and disposed on a lower side of the second semiconductor chip 120. For example, the third semiconductor chip 140 may be disposed on the bottom surface of the cavity C to be accommodated in the cavity C of the first package substrate 100, and the second semiconductor chip 120 may be disposed on the third semiconductor chip 140 to be accommodated in the cavity C at least partially.

Referring to FIG. 6, the first package 10 may include a third bump 136 interposed between the first package substrate 100 and the third semiconductor chip 140 to electrically connect the first package substrate 100 and the third semiconductor chip 140.

For example, the second chip pad 122 may be formed on the upper surface of the second semiconductor chip 120. The upper surface of the second semiconductor chip 120 where the second chip pad 122 is formed may be the active surface side of the second semiconductor chip 120. Further, a fourth chip pad 142 may be formed on one surface of the third semiconductor chip 140. A lower surface of the third semiconductor chip 140 where the fourth chip pad 142 is formed may be an active surface side of the third semiconductor chip 140. The second upper pad 104b may be formed on the periphery of the cavity C of an upper surfaces of the first package substrate 100, and the fourth upper pad 104d may be formed on the bottom surface of the cavity C.

The third semiconductor chip 140 may be disposed on the first package substrate 100 to be accommodated in the cavity C. In some example embodiments, the third semiconductor chip 140 may be disposed such that the surface where the fourth chip pad 142 is formed faces the bottom surface of the cavity C (e.g., faces the fourth upper pad 104d). Further, the second semiconductor chip 120 may be disposed on the third semiconductor chip 140 such that at least a portion thereof is accommodated in the cavity C. In some example embodiments, the second semiconductor chip 120 may be disposed such that the surface where the second chip pad 122 is formed faces upward.

The first bonding wire 134 may connect the second chip pad 122 and the second upper pad 104b. For example, the second semiconductor chip 120 and the first package substrate 100 may be electrically connected to each other through the first bonding wire 134, and signals and/or power may be transferred between the second semiconductor chip 120 and the first package substrate 100 through the first bonding wire 134.

Further, the third bump 136 may connect the fourth chip pad 142 and the fourth upper pad 104d. For example, the third semiconductor chip 140 and the first package substrate 100 may be electrically connected to each other through the third bump 136, and signals and/or power may be transferred between the third semiconductor chip 140 and the first package substrate 100 through the third bump 136.

The underfill layer U may cover the first bump 132 and at least a portion of the first bonding wire 134. An underfill solution may permeate into spaces between the second semiconductor chip 120 and the third semiconductor chip 140 and the wall surface of the cavity C such that the underfill layer U may cover a portion of the third bump 136. Referring to FIG. 7, one or more third semiconductor chips 140 may be disposed under the second semiconductor chip 120. For example, the one or more third semiconductor chips 140 may be disposed on the bottom surface of the cavity C to be accommodated in the cavity C of the first package substrate 100, and the second semiconductor chip 120 may be disposed on the one or more third semiconductor chips 140 to be accommodated in the cavity C at least partially.

At least one of the second semiconductor chip 120 and the third semiconductor chip 140 may include a through via 144. For example, the second semiconductor chip 120 may be electrically connected to the first package substrate 100 through the first bonding wire 134, and the second semiconductor chip 120 and the one or more third semiconductor chips 140 may be electrically connected to each other through the through via 144.

For example, the through via 144 may be a through silicon via (TSV). The through via 144 may include a conductive plug extending through the semiconductor substrate included in the semiconductor chip, and a conductive barrier film surrounding the conductive plug. For example, the conductive plug may have a cylindrical shape, and the conductive barrier film may have a cylindrical shape surrounding a sidewall of the conductive plug. A via insulating film may be interposed between the through via 144 and the semiconductor substrate, surrounding a sidewall of each through via 144. At least a portion of the through vias 144 (e.g., at least some of the through vias 144) may be used as an electrode for signal transmission, and at least another portion of the through vias 144 (e.g., at least some other of the through vias 144) may be used as an electrode for power transmission.

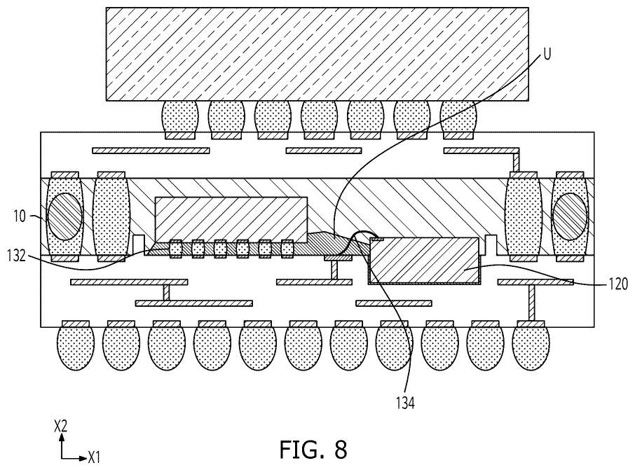

FIG. 8 is a cross-sectional view illustrating an example of the semiconductor package. Referring to FIG. 8, in the first package 10, the second semiconductor chip 120 may serve as a dam instead of the second dam D2. For example, at least a portion of the second semiconductor chip 120 (e.g., at least a portion of the side surface of the second semiconductor chip 120) may be in contact with the underfill layer U, and the second semiconductor chip 120 may limit and/or prevent the underfill layer U from overflowing. According to some example embodiments in which the second semiconductor chip 120 serves as a dam instead of the second dam D2, the underfill layer U may cover the first bump 132 and a portion of the first bonding wire 134 (e.g., a lower portion of the first bonding wire 134).

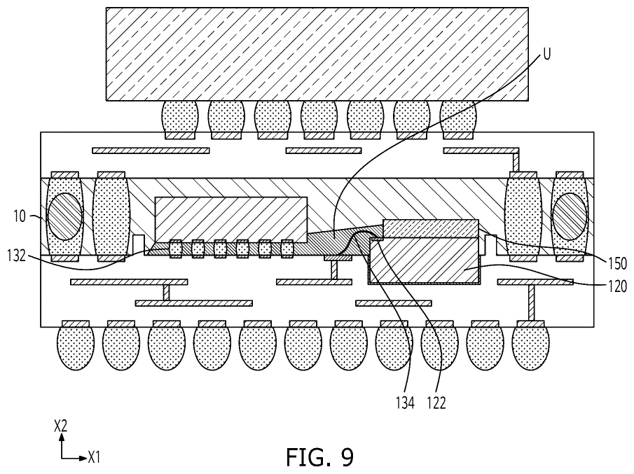

FIG. 9 is a cross-sectional view illustrating an example of the semiconductor package. Referring to FIG. 9, the first package 10 may include a dummy chip 150 disposed on the second semiconductor chip 120. For example, the dummy chip 150 may be disposed on the region of the upper surface of the second semiconductor chip 120 where the second chip pad 122 is not formed. In some example embodiments, the first bonding wire 134 may be positioned between the first bump 132 and the dummy chip 150.

At least a portion of the dummy chip 150 (e.g., at least a portion of a side surface of the dummy chip 150) may be in contact with the underfill layer U, and the dummy chip 150 may limit and/or prevent the underfill layer U from overflowing. For example, the dummy chip 150 stacked on the second semiconductor chip 120 may serve as a dam.

The dummy chip 150 may include silicon and/or a material (e.g., germanium, etc.) having properties similar to silicon. For example, the dummy chip 150 may be at least a portion of a bare wafer.

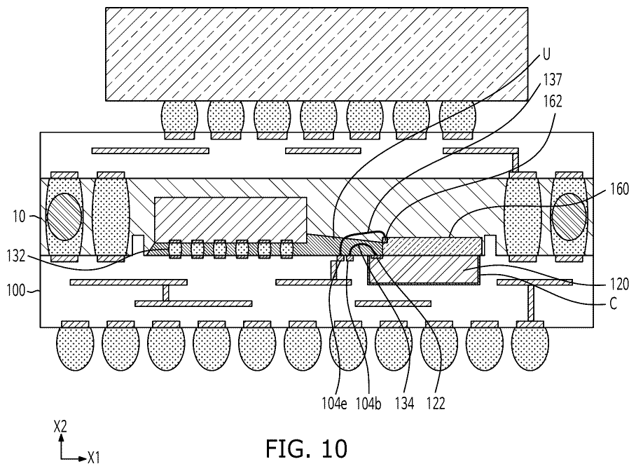

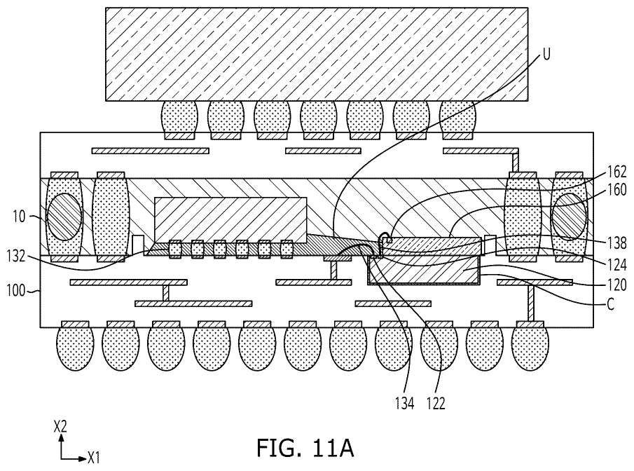

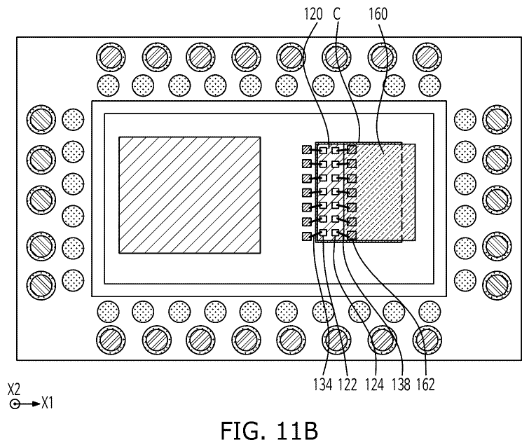

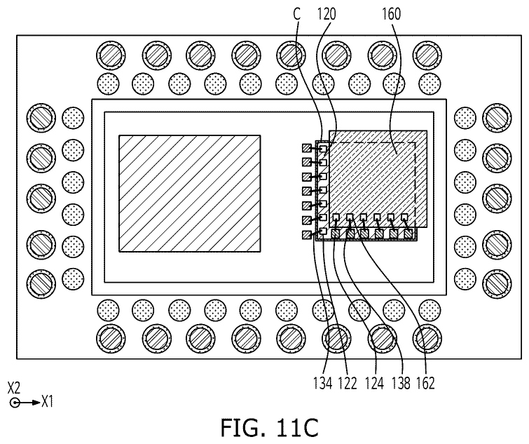

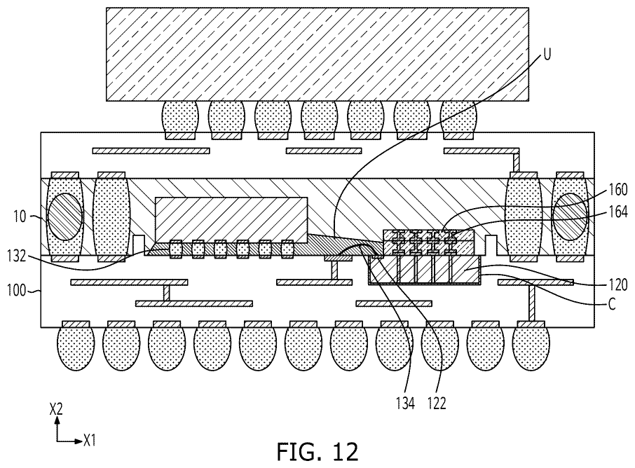

FIGS. 10 and 11A are cross-sectional views illustrating examples of the semiconductor package according to some example embodiments, and FIGS. 11B and 11C are plan views illustrating examples of the first package 10 according to some example embodiments. FIG. 12 is a cross-sectional view illustrating an example of the semiconductor package according to some example embodiments. For convenience of explanation, the illustrations of the underfill layer U, the molding layer M, and the second package substrate are omitted from the plan views of FIGS. 11B and 11C. Referring to FIGS. 10 to 12, the first package 10 may include a fourth semiconductor chip 160 disposed on the second semiconductor chip 120. For example, the fourth semiconductor chip 160 may be disposed on the region of the upper surface of the second semiconductor chip 120 where the second chip pad 122 is not formed. In some example embodiments, the first bonding wire 134 may be positioned between the first bump 132 and the fourth semiconductor chip 160. FIGS. 10 to 11C illustrate that only a portion of the fourth semiconductor chip 160 is positioned on the second semiconductor chip 120, but some example embodiments are not limited thereto. According to some example embodiments, the entire fourth semiconductor chip 160 may be positioned on the second semiconductor chip 120.

At least a portion of the fourth semiconductor chip 160 (e.g., at least a portion of a side surface of the fourth semiconductor chip 160) may be in contact with the underfill layer U, and the fourth semiconductor chip 160 may limit and/or prevent the underfill layer U from overflowing. For example, the fourth semiconductor chip 160 stacked on the second semiconductor chip 120 may serve as a dam.

Referring to FIG. 10, the first package 10 may include a second bonding wire 137 electrically connecting the first package substrate 100 and the fourth semiconductor chip 160. For example, a fifth chip pad 162 may be formed on one surface (e.g., upper surface) of the fourth semiconductor chip 160. The one surface of the fourth semiconductor chip 160 where the fifth chip pad 162 is formed may be an active surface side of the fourth semiconductor chip 160. The fourth semiconductor chip 160 may be disposed on the second semiconductor chip 120 such that the one surface where the fifth chip pad 162 is formed faces upward. Further, the first package substrate 100 may include a fifth upper pad 104e formed on the periphery of the cavity C of the upper surface. For example, the fifth upper pad 104e may be disposed between the second upper pad 104b and the first bump 132 in one direction (e.g., in the same direction as the direction in which the second upper pad 104b is disposed).

The second bonding wire 137 may connect the fifth chip pad 162 and the fifth upper pad 104e. For example, the fourth semiconductor chip 160 and the first package substrate 100 may be electrically connected to each other through the second bonding wire 137, and signals and/or power may be transferred between the fourth semiconductor chip 160 and the first package substrate 100 through the second bonding wire 137. At least a portion of the second bonding wire 137 may be covered by the underfill layer U. For example, as illustrated in FIG. 10, the underfill layer U may cover the first bump 132, at least a portion of the first bonding wire 134 (e.g., the entire first bonding wire 134), and at least a portion of the second bonding wire 137 (e.g., a lower portion of the second bonding wire 137).

Referring to FIGS. 11A to 11C, the first package 10 may include a third bonding wire 138 electrically connecting the second semiconductor chip 120 and the fourth semiconductor chip 160. For example, the fifth chip pad 162 may be formed on one surface (e.g., upper surface) of the fourth semiconductor chip 160.

A sixth chip pad 124 may be formed on the upper surface of the second semiconductor chip 120. The sixth chip pad 124 may be formed on the region of the upper surface of the second semiconductor chip 120 where the fourth semiconductor chip 160 is not disposed. For example, as illustrated in FIGS. 11A and 11B, the sixth chip pad 124 may be disposed between the second chip pad 122 formed at the periphery of a first edge of the second semiconductor chip 120 and the fourth semiconductor chip 160 in the same direction (e.g., in a third direction perpendicular to the first direction X1 and the second direction X2) as the direction in which the second chip pad 122 is disposed. In another example, as illustrated in FIG. 11C, the sixth chip pad 124 may be disposed on the periphery of a second edge of the second semiconductor chip 120 in a direction (e.g., in the first direction X1) different from the direction in which the second chip pad 122 is disposed.

The fourth semiconductor chip 160 may be disposed on the second semiconductor chip 120 such that the one surface where the fifth chip pad 162 is formed faces upward. The fourth semiconductor chip 160 may be disposed on the region of the upper surface of the second semiconductor chip 120 where the second chip pad 122 and the sixth chip pad 124 are not formed.

The third bonding wire 138 may connect the fifth chip pad 162 and the sixth chip pad 124. For example, the fourth semiconductor chip 160 and the second semiconductor chip 120 may be electrically connected to each other through the third bonding wire 138, and signals and/or power may be transferred between the fourth semiconductor chip 160 and the second semiconductor chip 120 through the third bonding wire 138. At least a portion of the third bonding wire 138 may be covered by the underfill layer U. For example, as illustrated in FIG. 11A, the underfill layer U may cover the first bump 132, at least a portion of the first bonding wire 134 (e.g., entire first bonding wire 134), and at least a portion of the third bonding wire 138 (e.g., a lower portion of the third bonding wire 138).

Referring to FIG. 12, one or more fourth semiconductor chips 160 may be disposed on the second semiconductor chip 120. At least one of the second semiconductor chip 120 or the fourth semiconductor chip 160 may include a through via 164. For example, the second semiconductor chip 120 may be electrically connected to the first package substrate 100 through the first bonding wire 134, and the second semiconductor chip 120 and the one or more fourth semiconductor chips 160 may be electrically connected to each other through the through via 164. At least a portion of the through vias 164 (e.g., at least some of the through vias 164) may be used as an electrode for signal transmission, and at least another portion of the through vias 164 (e.g., at least other of the through vias 164) may be used as an electrode for power transmission.

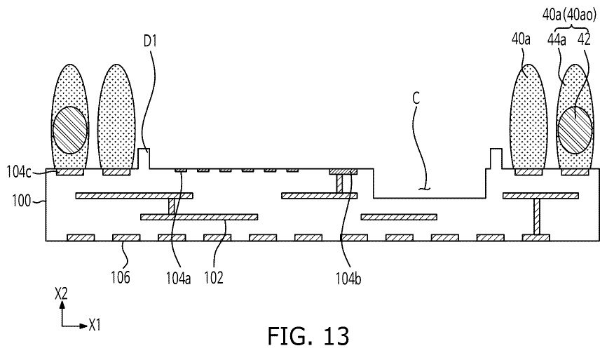

FIGS. 13 to 21 are cross-sectional views illustrating a process of manufacturing the semiconductor package according to some example embodiments.

Referring to FIG. 13, the process of manufacturing the semiconductor package may include preparing the first package substrate 100.

The first dam D1 may be formed on the first package substrate 100. For example, the first dam D1 may be formed as the substrate base protrudes from the upper surface of the first package substrate 100 in a vertical direction (in the second direction X2). The first dam D1 may be formed to surround a partial region of the first package substrate 100.

The cavity C may be formed in the first package substrate 100. For example, the cavity C may be formed in the first package substrate 100 as a portion of the upper surface of the first package substrate 100 is recessed toward the lower surface side. The cavity C may be formed in the region surrounded by the first dam D1.

The first package substrate 100 may include the first wiring layer 102, and the upper pads 104a, 104b, and 104c and the lower pad 106 electrically connected to the first wiring layer 102. The upper pads 104a, 104b, and 104c may be formed on the upper surface of the first package substrate 100, and the lower pad 106 may be formed on the lower surface of the first package substrate 100.

The upper pads 104a, 104b, and 104c may include the first upper pad 104a, the second upper pad 104b, and the third upper pad 104c. The first upper pad 104a and the second upper pad 104b may be formed on the upper surface of the first package substrate 100 in the region surrounded by the first dam D1, and the third upper pad 104c may be formed on the upper surface of the first package substrate 100 outside the region surrounded by the first dam D1. The second upper pad 104b may be formed on the periphery of a first cavity C of the upper surface of the first package substrate 100.

A first sub-connecting member 40a may be attached onto the third upper pad 104c of the first package substrate 100. The first sub-connecting member 40a may include a conductive material. For example, the first sub-connecting member may be a conductive post, a conductive pillar, a conductive bump, a solder ball, etc.

An outer first sub-connecting member 40ao disposed at the edge of the first sub-connecting member 40a may include a metal core ball 42 (e.g., a copper ball) therein. For example, the outer first sub-connecting member 40ao may be a connecting member in which the metal core ball 42 is impregnated in a conductive connecting member 44a.

A vertical connecting member (e.g., 40 in FIG. 3) instead of the first sub-connecting member 40a may be attached to the third upper pad 104c.

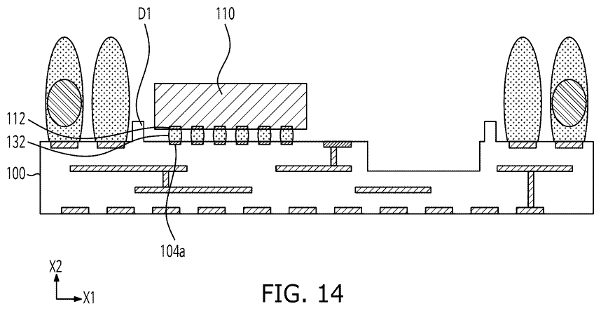

Referring to FIG. 14, the process of manufacturing the semiconductor package may include disposing the first semiconductor chip 110 on the first package substrate 100. For example, the first chip pad 112 may be formed on the first semiconductor chip 110. The first bump 132 (e.g., solder bump, etc.) may be formed on the first chip pad 112 of the first semiconductor chip 110. The first semiconductor chip 110 may be disposed such that the surface where the first chip pad 112 is formed faces the first upper pad 104a of the first package substrate 100. The first bump 132 formed on the first chip pad 112 may be in contact with the first upper pad 104a of the first package substrate 100.

For example, a reflow process or a thermal compression (TC) process may be performed while the first bump 132 of the first semiconductor chip 110 is in contact with the first upper pad 104a. The first bump 132 may be bonded to the first chip pad 112 and the first upper pad 104a by being fused at high temperature. The first semiconductor chip 110 and the first package substrate 100 may be electrically connected to each other through the first bump 132.

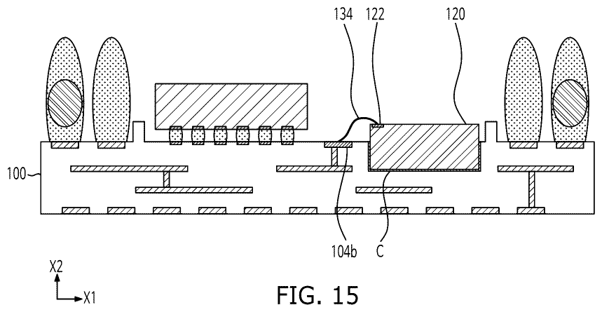

Referring to FIG. 15, the process of manufacturing the semiconductor package may include disposing the second semiconductor chip 120 on the first package substrate 100. The second semiconductor chip 120 may be disposed on the bottom surface of the cavity C such that at least a portion thereof is accommodated in the cavity C.

For example, the second chip pad 122 may be formed on the upper surface of the second semiconductor chip 120. The second semiconductor chip 120 may be disposed such that the upper surface where the second chip pad 122 is formed faces upward. The second semiconductor chip 120 may be disposed on (or attached onto) the bottom surface of the cavity C while a separate adhesive member (e.g., DAF) is attached to the lower surface of the second semiconductor chip 120 and/or the bottom surface of the cavity C.

The process of manufacturing the semiconductor package may include connecting the first bonding wire 134 to the first package substrate 100 and the second semiconductor chip 120. For example, the first bonding wire 134 may be connected to the second chip pad 122 and the second upper pad 104b by wire-bonding. The second semiconductor chip 120 and the first package substrate 100 may be mechanically and electrically connected to each other by the first bonding wire 134.

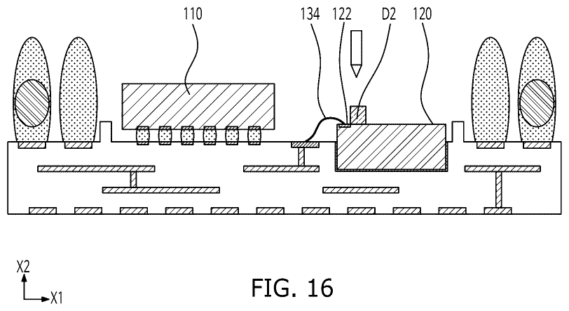

Referring to FIG. 16, the process of manufacturing the semiconductor package may include forming the second dam D2 on the second semiconductor chip 120. The second dam D2 may be formed on the second semiconductor chip 120 in a direction opposite to the direction of the first semiconductor chip 110 with respect to the second chip pad 122.

The second chip pad 122 may be formed to be disposed on the upper surface of the second semiconductor chip 120 in one direction (e.g., in a direction perpendicular to the first direction X1 and the second direction X2). In some example embodiments, the second dam D2 may be formed on the upper surface of the second semiconductor chip 120 to extend in the same direction as the direction in which the second chip pad 122 is disposed.

The second dam D2 may include an epoxy resin, but is not limited thereto. For example, the second dam D2 may be formed of any material such as silicon, polyimide, polyurethane, etc.

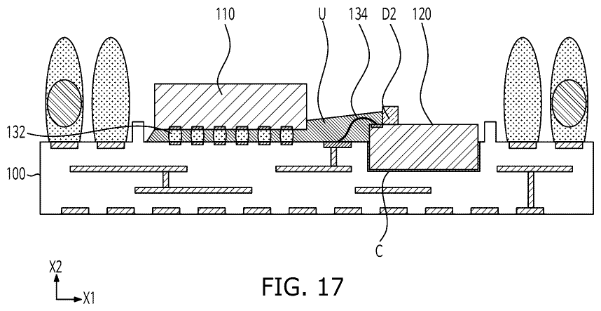

Referring to FIG. 17, the process of manufacturing the semiconductor package may include forming the underfill layer U that covers the first bump 132 and at least a portion of the first bonding wire 134. The underfill layer U may be formed by a capillary underfill (CUF) process, but is not limited thereto. According to some example embodiments, the underfill layer U may be formed by a molded underfill (MUF) process.

According to a comparative example in which the wire bonding process of connecting the first bonding wire 134 to the first package substrate 100 and the second semiconductor chip 120 is performed after the underfill process, the underfill solution may flow or overflow, disrupting the wire bonding process, such as stopping the wire bonding facility, etc. According to some example embodiments of the present disclosure, the underfill process in which the underfill layer U covers the first bump 132 and at least a portion of the first bonding wire 134 together may be performed after the wire bonding process of connecting the first bonding wire 134 to the first package substrate 100 and the second semiconductor chip 120 is performed, such that the wire bonding process may be performed more effectively.

Further, the underfill layer U may be in contact with at least a portion of the second dam D2 and/or at least a portion of the second semiconductor chip 120. For example, the underfill layer U may be in contact with at least a portion of the side surface of the second dam D2 and/or at least a portion of the side surface of the second semiconductor chip 120. For example, the second dam D2 and/or the second semiconductor chip 120 may serve as a dam to limit and/or prevent overflowing of the underfill solution. An underfill solution may partially permeate into a space between the second semiconductor chip 120 and the wall surface of the cavity C, forming the underfill layer U also in the space between the second semiconductor chip 120 and the wall surface of the cavity C.

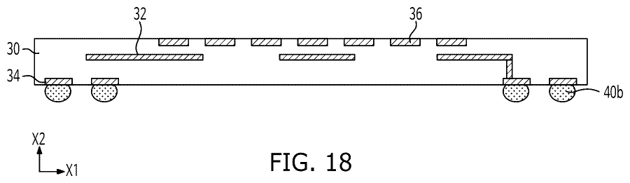

Referring to FIG. 18, the process of manufacturing the semiconductor package may include preparing the second package substrate 30.

The second package substrate 30 may include the second wiring layer 32, and the lower pad 34 and the upper pad 36 electrically connected to the second wiring layer 32. The lower pad 34 may be formed on the lower surface of the second package substrate 30, and the upper pad 36 may be formed on the upper surface of the second package substrate 30.

A second sub-connecting member 40b may be attached onto the lower pad 34 of the second package substrate 30. The second sub-connecting member 40b may include a conductive material. For example, the second sub-connecting member 40b may be a conductive post, a conductive pillar, a conductive bump, a solder ball, etc. The second sub-connecting member 40b may be omitted.

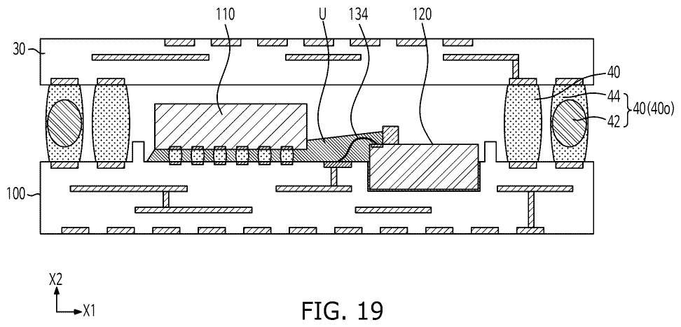

Referring to FIG. 19, the process of manufacturing the semiconductor package may include disposing the second package substrate 30 on the first package substrate 100 and forming the vertical connecting member 40 connecting the first package substrate 100 and the second package substrate 30.

For example, the second package substrate 30 may be disposed such that the second sub-connecting member (40b of FIG. 18) faces the first sub-connecting member (40a of FIG. 13) attached to the first package substrate 100. The second sub-connecting member may be in contact with the first sub-connecting member.

For example, while the second sub-connecting member is in contact with the first sub-connecting member, a reflow process or a thermo compression (TC) process may be performed. The vertical connecting member 40 may be formed as the first sub-connecting member and the second sub-connecting member are fused at high temperature. The first package substrate 100 and the second package substrate 30 may be electrically connected to each other through the vertical connecting member 40. An outer vertical connecting member 400 disposed at the edge of the vertical connecting member 40 may be formed in a form in which the metal core ball 42 is impregnated in the conductive connecting member 44.

According to some example embodiments, the vertical connecting member 40, instead of the first sub-connecting member 40a, may be attached to the first package substrate 100, and the second sub-connecting member 40b may be omitted from the second package substrate 30. In some example embodiments, a reflow process or a thermo compression process is performed while the vertical connecting member 40 attached to the first package substrate 100 is in contact with the second package substrate 30, such that the vertical connecting member 40 may be fused at high temperature to be bonded to the second package substrate 30.

After the second package substrate 30 is disposed on the first package substrate 100 and the vertical connection member 40 is formed, a cleaning process (e.g., interposer OPS cleaning process, etc.) may be performed. According to a comparative example, the first bonding wire 134 is not covered by the underfill layer U, and as a result, physical deformation (e.g., sweeping or breaking) may occur in the first bonding wire 134 during the cleaning process. According to some example embodiments of the present disclosure, since at least a portion of the first bonding wire 134 is covered by the underfill layer U, the physical deformation of the first bonding wire 134 may be limited and/or prevented during the cleaning process.

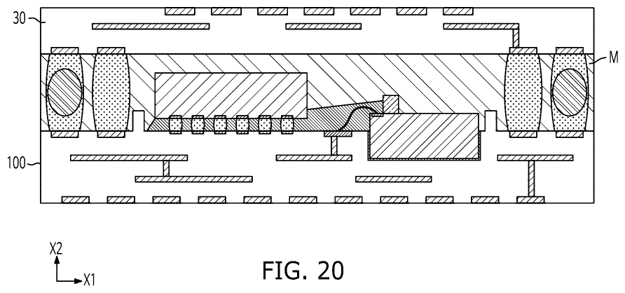

Referring to FIG. 20, the process of manufacturing the semiconductor package may include forming the molding layer M between the first package substrate 100 and the second package substrate 30.

For example, the molding layer M may cover the spaces between the first package substrate 100 and the second package substrate 30 excluding the spaces occupied by the other components.

The molding layer M may include an epoxy molding compound (EMC). However, some example embodiments are not limited to the above, and the molding layer M may include various materials such as epoxy-based materials, thermosetting materials, thermoplastic materials, UV-treated materials, etc.

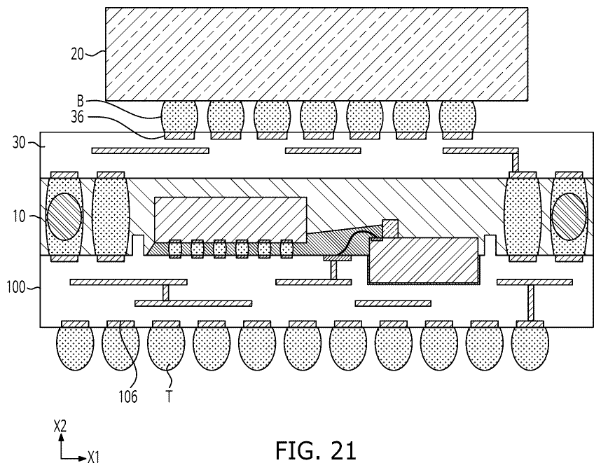

Referring to FIG. 21, the process of manufacturing the semiconductor package may include disposing the second package 20 on the first package 10. For example, the second package 20 may be disposed on the second package substrate 30 such that the connection terminal B is connected to the upper pad 36 of the second package substrate 30 and the second package 20. The second package substrate 30 may serve as an interposer.

Further, the process of manufacturing the semiconductor package may include attaching the external terminal T to the lower pad 106 of the first package substrate 100. Accordingly, the semiconductor package may be manufactured.

The process of manufacturing the semiconductor package described above with reference to FIGS. 13 to 21 is merely an example, and some example embodiments are not limited thereto. At least one operation may be added, changed, or omitted, or an order of operations may be changed. For example, the second package 20 may be disposed on the first package 10 after the external terminal is attached to the lower pad 106 of the first package substrate 100.

1. A semiconductor package, comprising:
a package substrate defining a cavity therein;
a first semiconductor chip on the package substrate;
a first bump between the package substrate and the first semiconductor chip, the first bump electrically connecting the package substrate and the first semiconductor chip;
a second semiconductor chip on the package substrate, the second semiconductor chip being at least partially in the cavity;
a first bonding wire electrically connecting the package substrate and the second semiconductor chip; and
an underfill layer covering the first bump and at least a portion of the first bonding wire.

2. The semiconductor package according to claim 1, wherein
the package substrate includes a first dam protruding therefrom, the first dam surrounding the first semiconductor chip and the second semiconductor chip, and
the underfill layer is in a region surrounded by the first dam.

3. The semiconductor package according to claim 1, further comprising a second dam on the second semiconductor chip, wherein the first bonding wire is between the first bump and the second dam.

4. The semiconductor package according to claim 3, wherein the underfill layer contacts at least a portion of the second dam.

5. The semiconductor package according to claim 1, wherein the underfill layer contacts at least a portion of a side surface of the second semiconductor chip.

6. The semiconductor package according to claim 1, further comprising a second bump between the package substrate and the second semiconductor chip, the second bump electrically connecting the package substrate and the second semiconductor chip.

7. The semiconductor package according to claim 1, further comprising a third semiconductor chip in the cavity and on a lower side of the second semiconductor chip.

8. The semiconductor package according to claim 7, further comprising a second bump between the package substrate and the third semiconductor chip, the second bump electrically connecting the package substrate and the third semiconductor chip.

9. The semiconductor package according to claim 7, wherein
at least one of the second semiconductor chip or the third semiconductor chip includes a through via, and
the second semiconductor chip and the third semiconductor chip are electrically connected through the through via.

10. The semiconductor package according to claim 1, wherein
a first chip pad is on a surface of the first semiconductor chip,
the first semiconductor chip is on the package substrate such that the surface faces the package substrate, and
the first bump is connected to the first chip pad.

11. The semiconductor package according to claim 1, wherein
a first chip pad on an upper surface of the second semiconductor chip, and
the first bonding wire is connected to the first chip pad.

12. The semiconductor package according to claim 11, wherein
the semiconductor package further includes a dummy chip on the second semiconductor chip,
the dummy chip is on a region of the upper surface of the second semiconductor chip where the first chip pad is not, and
the first bonding wire is between the first bump and the dummy chip.

13. The semiconductor package according to claim 12, wherein the underfill layer contacts at least a portion of a side surface of the dummy chip.

14. The semiconductor package according to claim 11, further comprising a third semiconductor chip on the second semiconductor chip,
wherein the third semiconductor chip is on a region of the upper surface of the second semiconductor chip where the first chip pad is not, and
the first bonding wire is between the first bump and the third semiconductor chip.

15. The semiconductor package according to claim 14, wherein the underfill layer contacts at least a portion of a side surface of the third semiconductor chip.

16. The semiconductor package according to claim 14, further comprising a second bonding wire electrically connecting at least one of the package substrate or the second semiconductor chip, and the third semiconductor chip.

17. The semiconductor package according to claim 14, wherein
at least one of the second semiconductor chip or the third semiconductor chip includes a through via, and
the second semiconductor chip and the third semiconductor chip are electrically connected to each other through the through via.

18. The semiconductor package according to claim 1, wherein the first semiconductor chip is a modem chip, and the second semiconductor chip is a memory chip or a memory controller chip.

19. A semiconductor package, comprising:
a first package; and
a second package on the first package, the second package including one or more semiconductor chips,
wherein the first package includes
a first package substrate defining a cavity therein,
an interposer apart from the first package substrate, the interposer electrically connecting the first package and the second package,
a vertical connecting member between the first package substrate and the interposer, the vertical connecting member electrically connecting the first package substrate and the interposer,
a first semiconductor chip on the first package substrate;
a first bump between the first package substrate and the first semiconductor chip, the first bump electrically connecting the first package substrate and the first semiconductor chip,
a second semiconductor chip on the first package substrate, the second semiconductor chip at least partially in the cavity,
a first bonding wire electrically connecting the first package substrate and the second semiconductor chip, and
an underfill layer covering the first bump and at least a portion of the first bonding wire.

20. A semiconductor package, comprising:
a first package substrate defining a cavity therein;
a second package substrate spaced apart from the first package substrate;
a vertical connecting member between the first package substrate and the second package substrate, the vertical connecting member connecting the first package substrate and the second package substrate;
a first semiconductor chip on the first package substrate;
a first bump between the first package substrate and the first semiconductor chip, the first bump electrically connecting the first package substrate and the first semiconductor chip;
a second semiconductor chip on the first package substrate, the second semiconductor chip at least partially in the cavity;
a first bonding wire electrically connecting the first package substrate and the second semiconductor chip; and
an underfill layer covering the first bump and at least a portion of the first bonding wire.
